(19) United States
(12) Patent Application Publication
(10) Pub. No.: US 2025/0208516 A1
(43) Pub. Date: Jun. 26, 2025

(54) LASER APPARATUS AND ELECTRONIC DEVICE MANUFACTURING METHOD

(71) Applicant: Gigaphoton Inc., Tochigi (JP)

(72) Inventor: Yousuke FUJIMAKI, Oyama-shi (JP)

(73) Assignee: Gigaphoton Inc., Tochigi (JP)

(21) Appl. No.: 18/945,106

(22) Filed: Nov. 12, 2024

(30) Foreign Application Priority Data
Dec. 26, 2023 (JP) 2023-219064

(51) Int. Cl. G03F 7/00; G03F 7/20

(52) U.S. Cl. CPC G03F 7/70025; G03F 7/2006; G03F 7/2008; G03F 7/70041

(57) ABSTRACT

A laser apparatus includes: an oscillator configured to output seed light in a pulse form; a first amplifier configured to amplify the seed light and to output first amplified light; a first beam splitter configured to split the first amplified light into first split light and second split light having energy smaller than that of the first split light; a first delay optical system configured to delay the second split light; a second amplifier configured to amplify the delayed second split light and to output second amplified light; a beam combiner configured to combine the first split light and the second amplified light and to output combined light; and a pulse stretcher configured to stretch a pulse width of the combined light.

### CROSS-REFERENCE TO RELATED APPLICATIONS

The present application claims the benefit of Japanese Patent Application No. 2023-219064, filed on Dec. 26, 2023, the entire contents of which are hereby incorporated by reference.

### BACKGROUND

### 1. Technical Field

The present disclosure relates to a laser apparatus and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 μm to 400 μm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: U.S. Patent Application Publication No. 2008/144671
Patent Document 2: U.S. Patent Application Publication No. 2008/197299

### SUMMARY

A laser apparatus according to one aspect of the present disclosure includes an oscillator, a first amplifier, a first beam splitter, a first delay optical system, a second amplifier, a beam combiner, and a pulse stretcher. The oscillator is configured to output seed light in a pulse form. The first amplifier is configured to amplify the seed light and to output first amplified light. The first beam splitter is configured to split the first amplified light into first split light and second split light having energy smaller than that of the first split light. The first delay optical system is configured to delay the second split light. The second amplifier is configured to amplify the delayed second split light and to output second amplified light. The beam combiner is configured to combine the first split light and the second amplified light and to output combined light. The pulse stretcher is configured to stretch a pulse width of the combined light.

An electronic device manufacturing method according to one aspect of the present disclosure includes generating a laser beam with a laser apparatus, outputting the laser beam to an exposure apparatus, and exposing a photosensitive substrate to the laser beam within the exposure apparatus to manufacture an electronic device. The laser apparatus includes: an oscillator configured to output seed light in a pulse form; a first amplifier configured to amplify the seed light and to output first amplified light; a first beam splitter configured to split the first amplified light into first split light and second split light having energy smaller than that of the first split light; a first delay optical system configured to delay the second split light; a second amplifier configured to amplify the delayed second split light and to output second amplified light; a beam combiner configured to combine the first split light and the second amplified light and to output combined light; and a pulse stretcher configured to stretch a pulse width of the combined light.

### BRIEF DESCRIPTION OF THE DRAWINGS

Some embodiments of the present disclosure will be described below, by way of example only, with reference to the accompanying drawings.

FIG. 1 illustrates a configuration of an exposure system in a comparative example.

FIG. 2 illustrates a configuration of a laser apparatus according to the comparative example.

FIG. 3 schematically illustrates a configuration of a laser apparatus according to a first embodiment.

FIG. 4 is a time chart illustrating pulse time waveforms of an oscillation trigger signal and a laser beam of respective parts of the laser apparatus according to the first embodiment.

FIG. 5 schematically illustrates a configuration of a laser apparatus according to a second embodiment.

FIG. 6 is a time chart illustrating pulse time waveforms of the laser beam of respective parts of the laser apparatus according to the second embodiment.

FIG. 7 schematically illustrates a configuration of a laser apparatus according to a third embodiment.

FIG. 8 is a time chart illustrating pulse time waveforms of the laser beam of respective parts of the laser apparatus according to the third embodiment.

FIG. 9 is a flowchart of control of an applied voltage executed by a processor in the first to third embodiments.

FIG. 10 illustrates a configuration example of a first delay optical system used in the first and second embodiments.

FIG. 11 illustrates a first configuration example of a beam combiner used in the first embodiment.

FIG. 12 illustrates a second configuration example of the beam combiner used in the first embodiment.

FIG. 13 illustrates a third configuration example of the beam combiner used in the second embodiment.

### DESCRIPTION OF EMBODIMENTS

### Contents

1. Comparative Example
   1.1 Configuration of Exposure Apparatus 200
   1.2 Operation of Exposure Apparatus 200
   1.3 Configuration of Laser Apparatus 100
      1.3.1 First and Second Oscillators MO1 and MO2
      1.3.2 First and Second Amplifiers PO1 and PO2
      1.3.3 First and Second Pulse Stretchers PS1 and PS2
      1.3.4 Others
   1.4 Operation of Laser Apparatus 100
      1.4.1 First and Second Oscillators MO1 and MO2
      1.4.2 First and Second Amplifiers PO1 and PO2
      1.4.3 First and Second Pulse Stretchers PS1 and PS2
      1.4.4 Others
   1.5 Problem of Comparative Example
2. Laser Apparatus 100a that Branches First Amplified Light Bpoa
   2.1 Configuration
   2.2 Operation
      2.2.1 Timing Control
      2.2.2 Energy Control
   2.3 Effect
3. Laser Apparatus 100b that Further Branches Second Amplified Light Bpob
   3.1 Configuration
   3.2 Operation
      3.2.1 Timing Control
      3.2.2 Energy Control
   3.3 Effect
4. Laser Apparatus 100c that Further Branches Second Split Light Bpoa2
   4.1 Configuration
   4.2 Operation
      4.2.1 Timing Control
      4.2.2 Energy Control
   4.3 Effect
5. Others
   5.1 Control of Applied Voltage
   5.2 Configuration of Delay Optical System
   5.3 Configuration of Beam Combiner COM
   5.4 Supplements

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. COMPARATIVE EXAMPLE

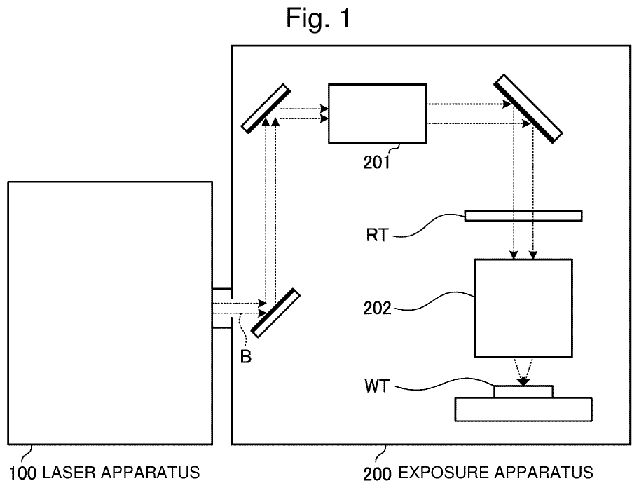

FIG. 1 schematically illustrates a configuration of an exposure system in a comparative example. The comparative example of the present disclosure is an example recognized by the applicant as known only by the applicant, and is not a publicly known example admitted by the applicant.

The exposure system includes a laser apparatus 100 and an exposure apparatus 200. The laser apparatus 100 is configured to output a laser beam B toward the exposure apparatus 200.

### 1.1 Configuration of Exposure Apparatus 200

The exposure apparatus 200 includes an illumination optical system 201 and a projection optical system 202. The illumination optical system 201 illuminates a reticle pattern of an unillustrated reticle disposed on a reticle stage RT with the laser beam B that has entered from the laser apparatus 100. The projection optical system 202 performs reduced projection of the laser beam B transmitted through the reticle, and forms an image on an unillustrated workpiece disposed on a workpiece table WT. The workpiece is a photosensitive substrate such as a semiconductor wafer on which a resist film is applied.

### 1.2 Operation of Exposure Apparatus 200

The exposure apparatus 200 causes the reticle stage RT and the workpiece table WT to be translated in directions opposite to each other in synchronization. As a result, the workpiece is exposed by the laser beam B reflecting the reticle pattern. By such an exposure process, the reticle pattern is transferred onto the semiconductor wafer. Thereafter, an electronic device can be manufactured through a plurality of processes.

### 1.3 Configuration of Laser Apparatus 100

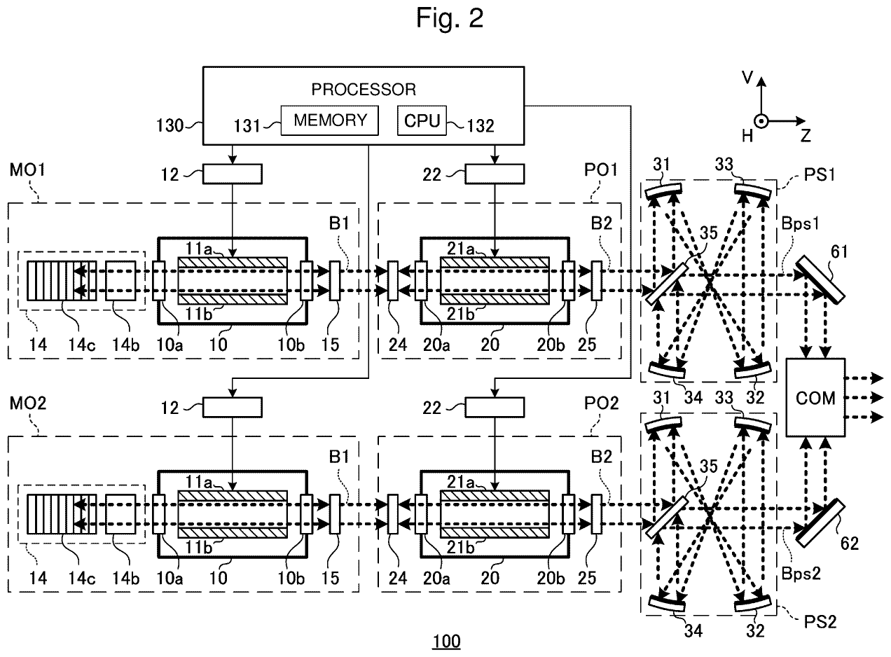

FIG. 2 illustrates a configuration of the laser apparatus 100 according to the comparative example. The laser apparatus 100 includes first and second oscillators MO1 and MO2, first and second amplifiers PO1 and PO2, first and second pulse stretchers PS1 and PS2, a beam combiner COM, and a processor 130.

### 1.3.1 First and Second Oscillators MO1 and MO2

The first and second oscillators MO1 and MO2 have the same configuration. Each of the first and second oscillators MO1 and MO2 is a master oscillator including a laser chamber 10, a pair of discharge electrodes 11a and 11b, a line narrowing module 14, and an output coupling mirror 15.

The line narrowing module 14 and the output coupling mirror 15 form a laser resonator. The laser chamber 10 is disposed in an optical path of the laser resonator. Windows 10a and 10b are provided on both ends of the laser chamber 10. The discharge electrodes 11a and 11b are disposed inside the laser chamber 10. A pulse power source 12 is connected to the discharge electrode 11a. The laser chamber 10 is filled with a laser gas containing, for example, an argon gas or a krypton gas as a rare gas, a fluorine gas as a halogen gas, and a neon gas as a buffer gas, or the like.

The line narrowing module 14 includes a prism 14b and a grating 14c. The prism 14b is disposed in an optical path of light output through the window 10a. The grating 14c is disposed in an optical path of light transmitted through the prism 14b. The output coupling mirror 15 is a partial reflective mirror, and is disposed in an optical path of light output through the window 10b.

### 1.3.2 First and Second Amplifiers PO1 and PO2

The first amplifier PO1 is disposed in an optical path of seed light B1 output from the first oscillator MO1, and the second amplifier PO2 is disposed in an optical path of the seed light B1 output from the second oscillator MO2. The first and second amplifiers PO1 and PO2 have the same configuration. Each of the first and second amplifiers PO1 and PO2 is a power oscillator including a laser chamber 20, a pair of discharge electrodes 21a and 21b, a rear mirror 24, and an output coupling mirror 25.

Each of the rear mirror 24 and the output coupling mirror 25 is a partial reflective mirror. A reflectance of the rear mirror 24 is set higher than a reflectance of the output coupling mirror 25. The rear mirror 24 and the output coupling mirror 25 form a laser resonator. The laser chamber 20 is disposed in an optical path of the laser resonator. Windows 20a and 20b are provided on both ends of the laser chamber 20. The discharge electrodes 21a and 21b are disposed inside the laser chamber 20. A pulse power source 22 is connected to the discharge electrode 21a. The laser chamber 20 is filled with a laser gas similar to that in the laser chamber 10.

A discharge direction between the discharge electrodes 11a and 11b and between the discharge electrodes 21a and 21b is defined as a V direction or a −V direction. An output direction of the seed light B1 through the output coupling mirror 15 is defined as a Z direction. The V direction and the Z direction are directions perpendicular to each other, and the directions perpendicular to both of them are an H direction and a −H direction.

### 1.3.3 First and Second Pulse Stretchers PS1 and PS2

The first pulse stretcher PS1 is disposed in an optical path of a laser beam B2 output from the first amplifier PO1, and the second pulse stretcher PS2 is disposed in an optical path of the laser beam B2 output from the second amplifier PO2. The first and second pulse stretchers PS1 and PS2 have the same configuration. Each of the first and second pulse stretchers PS1 and PS2 includes first to fourth concave mirrors 31-34 and a beam splitter 35. Each of the first to fourth concave mirrors 31-34 is a spherical mirror.

### 1.3.4 Others

High reflective mirrors 61 and 62 are disposed in optical paths of laser beams Bps1 and Bps2 output from the first and second pulse stretchers PS1 and PS2, respectively.

The beam combiner COM is disposed in a space including optical paths of both the laser beams Bps1 and Bps2 reflected by the high reflective mirrors 61 and 62, respectively.

The processor 130 is a processing device including a memory 131 in which a control program is stored, and a CPU (central processing unit) 132 which executes the control program. The processor 130 is specifically configured or programmed to execute various kinds of processes included in the present disclosure.

### 1.4 Operation of Laser Apparatus 100

### 1.4.1 First and Second Oscillators MO1 and MO2

In each of the first and second oscillators MO1 and MO2, when a high voltage pulse generated by the pulse power source 12 is applied to the discharge electrode 11a, discharge occurs inside the laser chamber 10. By energy of the discharge, a laser medium in the laser chamber 10 is excited and shifts to a high energy level. When the excited laser medium then shifts to a low energy level, light having a wavelength corresponding to the energy level difference is discharged. The light generated inside the laser chamber 10 is output to an outside of the laser chamber 10 through the windows 10a and 10b.

The light output through the window 10a of the laser chamber 10 is stretched in a beam width in the H direction by the prism 14b, and enters the grating 14c. The light that has entered the grating 14c from the prism 14b is reflected by a plurality of grooves of the grating 14c, and is also diffracted in a direction corresponding to the wavelength of the light. The prism 14b reduces the beam width in the H direction of diffracted light from the grating 14c and returns the light to the laser chamber 10 through the window 10a.

The output coupling mirror 15 transmits and outputs a part of the light output through the window 10b of the laser chamber 10, and reflects the other part back to the inside of the laser chamber 10 through the window 10b.

In this way, the light output from the laser chamber 10 reciprocates between the line narrowing module 14 and the output coupling mirror 15, and is amplified every time it passes through a discharge space inside the laser chamber 10. The light is line-narrowed every time it is turned back in the line narrowing module 14. The light laser-oscillated and band-narrowed in this way is output as the seed light B1 through the output coupling mirror 15.

### 1.4.2 First and Second Amplifiers PO1 and PO2

In each of the first and second amplifiers PO1 and PO2, a high voltage pulse generated by the pulse power source 22 is applied to the discharge electrode 21a. A time period from the time when the processor 130 transmits an oscillation trigger signal to the pulse power source 12 to the time when the processor 130 transmits the oscillation trigger signal to the pulse power source 22 is set so as to synchronize a timing at which the seed light B1 enters the inside of the laser chamber 20 and a timing at which the discharge occurs inside the laser chamber 20.

The seed light B1 reciprocates between the rear mirror 24 and the output coupling mirror 25, and is amplified every time it passes through the discharge space inside the laser chamber 20. The amplified laser beam B2 is output through the output coupling mirror 25.

### 1.4.3 First and Second Pulse Stretchers PS1 and PS2

In each of the first and second pulse stretchers PS1 and PS2, the beam splitter 35 transmits a part of the laser beam B2 incoming in the Z direction from the output coupling mirror 25 as first output light in the Z direction, and reflects the other part in the V direction.

The first to fourth concave mirrors 31-34 sequentially reflect the laser beam B2 reflected in the V direction by the beam splitter 35, and make the laser beam B2 enter the beam splitter 35 in the V direction. At the time, a beam cross section of the laser beam B2 that has arrived at the beam splitter 35 in the Z direction is image-formed on the beam splitter 35 in a size of 1:1 by the first to fourth concave mirrors 31-34. The beam splitter 35 reflects a part of the laser beam B2 incoming in the V direction from the fourth concave mirror 34 as second output light in the Z direction, and transmits the other part in the V direction.

Between the first output light and the second output light, there is a time difference corresponding to the time during which the light travels one cycle in a delay optical path formed by the first to fourth concave mirrors 31-34. By spatially overlapping the first output light and the second output light, the laser beams Bps1 and Bps2 having a stretched pulse width can be output.

By stretching the pulse width of the laser beam, generation of speckles on a surface of the semiconductor wafer exposed by the exposure apparatus 200 is suppressed. The speckles are light and dark spots generated by interference when the laser beam is scattered in order to make a light intensity distribution of the laser beam uniform. Intensity of speckles is expressed by speckle contrast SC and can be calculated by an equation below.

SC=(λ²/(A·Ω)+τ_{C}/TIS)^{1/2}

Here, λ is a wavelength, A is area of the beam cross section, Ω is a beam divergence angle, τ_{C} is coherence time, and TIS is a pulse width calculated by an equation below.

TIS=([∫I(t)dt]²)/(∫I(t)²dt)

Here, t is time and I(t) is light intensity at the time t.

### 1.4.4 Others

The high reflective mirrors 61 and 62 reflect the laser beams Bps1 and Bps2 toward the beam combiner COM, respectively. The beam combiner COM brings optical paths of the laser beams Bps1 and Bps2 close to each other to combine the laser beams Bps1 and Bps2, and outputs combined light.

The processor 130 controls an applied voltage of the first and second oscillators MO1 and MO2 generated by the pulse power source 12 and an applied voltage of the first and second amplifiers PO1 and PO2 generated by the pulse power source 22 so that energy of one pulse of the seed light B1 and energy of one pulse of the laser beam B2 have respective desired values. Further, the processor 130 transmits an oscillation trigger signal to the pulse power sources 12 and 22 so that a repetition frequency of the combined light output from the beam combiner COM becomes a desired value.

In order to improve a processing speed of the semiconductor wafer in the exposure apparatus 200, it is required to increase output energy of the laser apparatus 100. As a method of increasing the output energy of the laser apparatus 100, a method of increasing the repetition frequency and a method of increasing the energy per pulse are conceivable. However, when the repetition frequency is increased, next discharge is sometimes performed before discharge products between the discharge electrodes 11a and 11b and between the discharge electrodes 21a and 21b are removed after discharge of one time, which can make the discharge unstable. Alternatively, when a rotation speed of an unillustrated fan is increased in order to remove discharge products in a short time, power consumption increases. Further, when the repetition frequency is increased, influence of acoustic waves becomes large, which deteriorates light quality. On the other hand, since increase in energy per pulse increases peak intensity, an optical element is easily deteriorated by two-photon absorption.

Therefore, the processor 130 alternately transmits the oscillation trigger signal to the pulse power sources 12 of the first and second oscillators MO1 and MO2. When the repetition frequency of the oscillation trigger signal of each of the first and second oscillators MO1 and MO2 is 6 kHz, the repetition frequency of the combined light can be 12 kHz. As compared with a case where laser oscillation is performed at the repetition frequency of 12 kHz by one oscillator and one amplifier, a possibility of unstable discharge can be reduced according to the configuration of the comparative example since the first and second oscillators MO1 and MO2 and the first and second amplifiers PO1 and PO2 perform the laser oscillation at the repetition frequency of 6 kHz. Further, as compared with a case where the laser oscillation is performed at the repetition frequency of 6 kHz by one oscillator and one amplifier, the deterioration of the optical element is suppressed according to the configuration of the comparative example since the energy of the laser beam per unit time is increased even without increasing the peak intensity of the laser beam.

### 1.5 Problem of Comparative Example

In the comparative example, the first and second oscillators MO1 and MO2 and the first and second amplifiers PO1 and PO2 are required. Since the laser chamber 10 and the line narrowing module 14 are included in each of the first and second oscillators MO1 and MO2, there are problems that the laser apparatus 100 becomes expensive and an installation space becomes large.

### 2. LASER APPARATUS 100a THAT BRANCHES FIRST AMPLIFIED LIGHT BPOA

### 2.1 Configuration

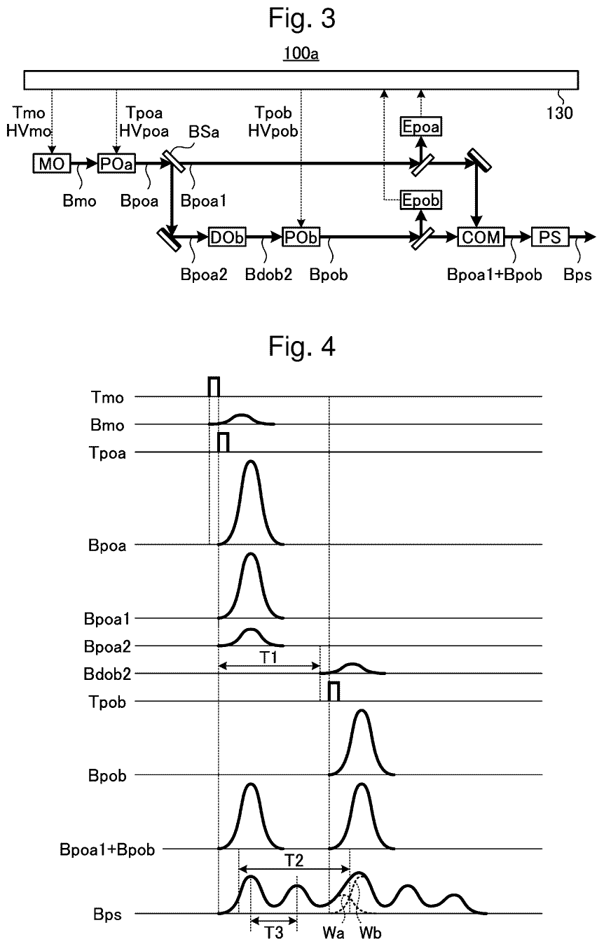

FIG. 3 schematically illustrates a configuration of a laser apparatus 100a according to a first embodiment. The laser apparatus 100a includes an oscillator MO, first and second amplifiers POa and POb, a first beam splitter BSa, a first delay optical system DOb, the beam combiner COM, a pulse stretcher PS, and the processor 130. While FIG. 3 illustrates some high reflective mirrors for changing a traveling direction of light, the traveling direction of the light and disposition of the high reflective mirrors are not limited to those illustrated.

Configurations of the oscillator MO, the first and second amplifier POa and POb, the beam combiner COM, the pulse stretcher PS, and the processor 130 are the same as those of the first oscillator MO1, the first and second amplifier PO1 and PO2, the beam combiner COM, the first pulse stretcher PS1, and the processor 130 in the comparative example.

The oscillator MO outputs seed light Bmo in a pulse form. The first amplifier POa is disposed in an optical path of the seed light Bmo, amplifies the seed light Bmo, and outputs first amplified light Bpoa.

The first beam splitter BSa is disposed in an optical path of the first amplified light Bpoa and splits the first amplified light Bpoa into first split light Bpoa1 and second split light Bpoa2. The second split light Bpoa2 has energy smaller than that of the first split light Bpoa1. When the first split light Bpoa1 is light transmitted through the first beam splitter BSa and the second split light Bpoa2 is light reflected by the first beam splitter BSa, it is desirable that a transmittance of the first beam splitter BSa is equal to or higher than 80% and equal to or lower than 96%.

The first delay optical system DOb is disposed in an optical path of the second split light Bpoa2, delays the second split light Bpoa2, and outputs it as second split light Bdob2. The first delay optical system DOb includes a delay optical path formed of a relay optical system including a plurality of concave mirrors. A configuration of the first delay optical system DOb will be described later with reference to FIG. 10. The second amplifier POb is disposed in an optical path of the delayed second split light Bdob2, amplifies the second split light Bdob2, and outputs second amplified light Bpob.

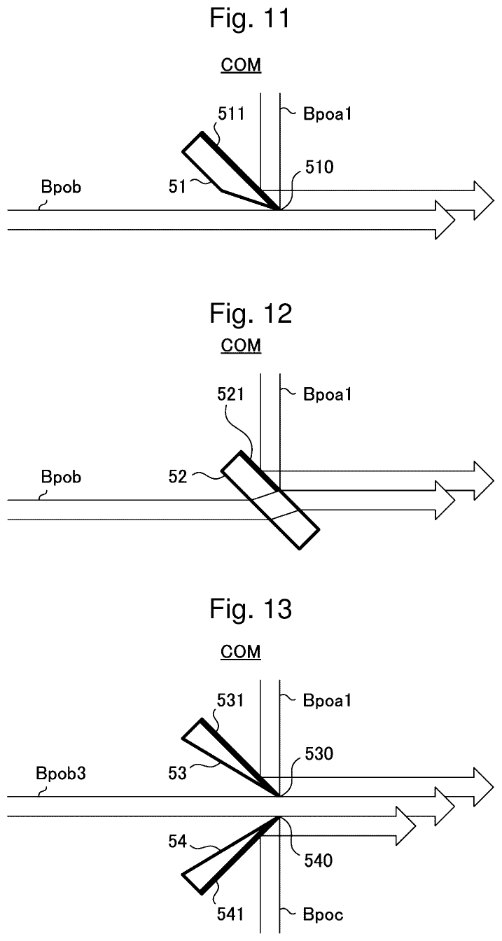

The beam combiner COM is disposed in a space including optical paths of both the first split light Bpoa1 and the second amplified light Bpob. The beam combiner COM brings the optical paths of the first split light Bpoa1 and the second amplified light Bpob close to each other to combine the first split light Bpoa1 and the second amplified light Bpob, and outputs combined light Bpoa1+Bpob. A configuration of the beam combiner COM will be described later with reference to FIG. 11 and FIG. 12.

The pulse stretcher PS is disposed in an optical path of the combined light Bpoa1+Bpob, stretches a pulse width of the combined light Bpoa1+Bpob, and outputs output light Bps. In addition to the pulse stretcher PS disposed in the optical path of the combined light Bpoa1+Bpob, or instead of the pulse stretcher PS, an unillustrated pulse stretcher may be disposed in each of the optical path of the first split light Bpoa1 and the optical path of the second amplified light Bpob. However, by disposing the pulse stretcher PS in the optical path of the combined light Bpoa1+Bpob, the number of stages and an optical path length of the pulse stretcher included in the laser apparatus 100a can be reduced.

A beam splitter having a transmittance higher than a reflectance thereof is disposed in each of the optical paths of the first split light Bpoa1 and the second amplified light Bpob. A first energy sensor Epoa and a second energy sensor Epob are disposed in respective optical paths of the light reflected by the beam splitters.

### 2.2 Operation

FIG. 4 is a time chart illustrating pulse time waveforms of the oscillation trigger signal and the laser beam of respective parts of the laser apparatus 100a according to the first embodiment. A horizontal axis in FIG. 4 indicates time, and vertical dashed lines in FIG. 4 indicate that events on the same dashed line occur at substantially the same time.

### 2.2.1 Timing Control

The processor 130 outputs oscillation trigger signals Tmo, Tpoa, and Tpob to the oscillator MO and the first and second amplifiers POa and POb, respectively. The oscillator MO and the first and second amplifiers POa and POb output the seed light Bmo and the first and second amplified light Bpoa and Bpob according to the oscillation trigger signals Tmo, Tpoa, and Tpob, respectively.

A time period from the time when the processor 130 outputs the oscillation trigger signal Tmo to the oscillator MO to the time when the processor 130 outputs the oscillation trigger signal Tpoa to the first amplifier POa is set so as to optimize parameters such as the energy, energy stability, and a spectral linewidth or the like of the first amplified light Bpoa.

A ratio of the energy of the first and second split light Bpoa1 and Bpoa2 is determined by the transmittance of the first beam splitter BSa.

Delay time T1 of the delayed second split light Bdob2 with respect to the second split light Bpoa2 is determined by an optical path length of the delay optical path of the first delay optical system DOb. A time period from the time when the processor 130 outputs the oscillation trigger signal Tpoa to the first amplifier POa to the time when the processor 130 outputs the oscillation trigger signal Tpob to the second amplifier POb is set so as to optimize parameters such as the energy, the energy stability, and the spectral linewidth or the like of the second amplified light Bpob, and becomes longer when the delay time T1 is longer.

A pulse time waveform of the output light Bps output from the pulse stretcher PS corresponds to a synthetic waveform of a pulse time waveform Wa of the stretched first split light Bpoa1 obtained by the pulse width of the first split light Bpoa1 being stretched by the pulse stretcher PS and a pulse time waveform Wb of the stretched second amplified light Bpob obtained by the pulse width of the second amplified light Bpob being stretched by the pulse stretcher PS.

The delay time T1 of the second split light Bdob2 delayed by the first delay optical system DOb is desirably equal to or higher than 60% and equal to or lower than 120% of a pulse width T2 of the pulse time waveform Wa. When the pulse width T2 is 500 ns for example, a desirable range of the delay time T1 is equal to or longer than 300 ns and equal to or shorter than 600 ns. Further, since a light speed is 3.0×10⁸ m/s, a desirable range of the optical path length of the delay optical path of the first delay optical system DOb is equal to or longer than 90 m and equal to or shorter than 180 m. When the first delay optical system DOb is formed of 60 concave mirrors for example and a distance between concave mirrors adjacent to each other on the optical path is 2.5 m, the optical path length of the delay optical path can be set to 150 m and the delay time T1 can be set to 500 ns.

The pulse time waveform Wa may include a plurality of peaks. A time interval T3 between adjacent peaks may correspond to the time during which the light travels one cycle in the delay optical path included in the pulse stretcher PS. Since the optical path length of the first delay optical system DOb is longer than the optical path length of the pulse stretcher PS, the delay time T1 is longer than the time interval T3. The optical path length of the first delay optical system DOb is preferably twice or more the optical path length of the pulse stretcher PS. When the pulse stretcher PS has a configuration in which a plurality of stages of delay optical paths are connected in series, combinations of the number of times of one cycle in the delay optical paths vary so that the pulse time waveform Wa becomes a complicated waveform including a larger number of peaks. The same applies to the pulse time waveform Wb.

### 2.2.2 Energy Control

The energy of the seed light Bmo is measured by an unillustrated energy sensor, and the processor 130 controls an applied voltage HVmo of the oscillator MO based on the measurement result. In this way, the energy of the seed light Bmo is controlled to be within an appropriate range as the seed light of the first amplifier POa.

In the first delay optical system DOb, the second split light Bpoa2 is attenuated each time it is reflected by the concave mirrors. Therefore, the energy of the delayed second split light Bdob2 output from the first delay optical system DOb is smaller than energy of the second split light Bpoa2 entering the first delay optical system DOb. When the energy of the seed light of the second amplifier POb is equal to that of the seed light Bmo of the first amplifier POa, the energy of the second split light Bpoa2 entering the first delay optical system DOb is larger than the energy of the seed light Bmo.

For example, when the second split light Bpoa2 enters the delay optical path formed of 60 concave mirrors each having a reflectance of 99%, the energy of the delayed second split light Bdob2 is attenuated to the 60th power of 99%, that is, 54.7%. In a case where the energy of, for example, 0.5 mJ or more is required as the seed light of the second amplifier POb and the energy of one pulse of the first amplified light Bpoa is, for example, 10 mJ, when the transmittance of the first beam splitter BSa is 90%, it is possible to obtain the second split light Bdob2 sufficient as the seed light of the second amplifier POb. When the number of the concave mirrors is further increased from 60, for example, by making the transmittance of the first beam splitter BSa lower than 90%, it is possible to suppress the energy of the second split light Bdob2 from becoming insufficient.

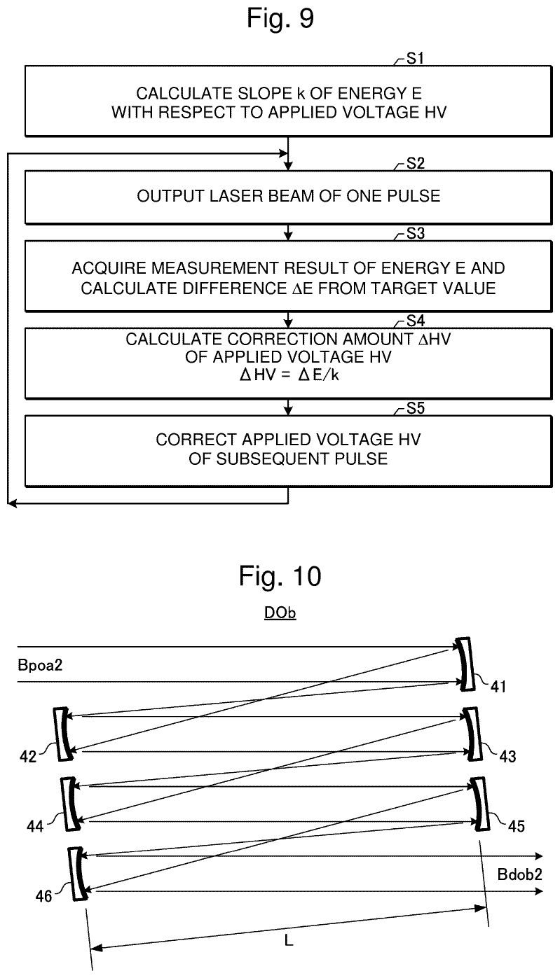

A pulse time waveform of the combined light Bpoa1+Bpob corresponds to a synthetic waveform of the first split light Bpoa1 and the second amplified light Bpob, and is controlled as follows. Energy of the first split light Bpoa1 and energy of the second amplified light Bpob are measured by the first and second energy sensors Epoa and Epob, respectively. The processor 130 controls an applied voltage HVpoa of the first amplifier POa based on a measurement result from the first energy sensor Epoa, and controls an applied voltage HVpob of the second amplifier POb based on a measurement result from the second energy sensor Epob. Control of the applied voltage based on the measurement result of the energy will be described later with reference to FIG. 9.

Alternatively, the pulse time waveform of the combined light Bpoa1+Bpob may be measured by an unillustrated energy sensor, and the processor 130 may calculate energy of a first portion corresponding to the first split light Bpoa1 of the pulse time waveform of the combined light Bpoa1+Bpob and energy of a second portion corresponding to the second amplified light Bpob. Further, the pulse time waveform of the output light Bps may be measured by an unillustrated energy sensor, and the processor 130 may calculate energy of the first portion corresponding to a part of the pulse time waveform Wa of the pulse time waveform of the output light Bps and energy of the second portion corresponding to a part of the pulse time waveform Wb. In any cases, the processor 130 may control the applied voltage HVpoa of the first amplifier POa based on the energy of the first portion and control the applied voltage HVpob of the second amplifier POb based on the energy of the second portion.

The first split light Bpoa1 and the second amplified light Bpob may have the same energy. Therefore, a difference in the energy between the first split light Bpoa1 and the second amplified light Bpob may be smaller than a difference in the energy between the first and second split light Bpoa1 and Bpoa2. Further, since the first split light Bpoa1 is generated by being branched from the first amplified light Bpoa, energy of the first amplified light Bpoa may be larger than the energy of the second amplified light Bpob.

### 2.3 Effect

(1) According to the first embodiment, the laser apparatus 100a includes the following components.
(a) The oscillator MO configured to output the seed light Bmo in a pulse form,
(b) the first amplifier POa configured to amplify the seed light Bmo and to output the first amplified light Bpoa,
(c) the first beam splitter BSa configured to split the first amplified light Bpoa into the first split light Bpoa1 and the second split light Bpoa2 having the energy smaller than that of the first split light Bpoa1,
(d) the first delay optical system DOb configured to delay the second split light Bpoa2,
(e) the second amplifier POb configured to amplify the delayed second split light Bdob2 and to output the second amplified light Bpob,
(f) the beam combiner COM configured to combine the first split light Bpoa1 and the second amplified light Bpob, and to output the combined light Bpoa1+Bpob, and
(g) the pulse stretcher PS configured to stretch the pulse width of the combined light Bpoa1+Bpob.

When the seed light Bmo output from the oscillator MO is split and made to enter the two amplifiers, output power of the oscillator MO needs to be doubled in order to make the split seed light Bmo be a light amount required in each of the two amplifiers, and a lifetime of the oscillator MO may be shortened. According to the first embodiment, since the first amplified light Bpoa is split in a stage subsequent to the first amplifier POa, even when just one oscillator MO is used and further even when the light is attenuated in the first delay optical system DOb, it is possible to obtain the second split light Bdob2 of the light amount sufficient as the seed light of the second amplifier POb while suppressing a load of the oscillator MO. Since one oscillator MO, one laser chamber 10, and one line narrowing module 14 are used, it is possible to suppress the laser apparatus 100 from becoming expensive and an installation space from becoming large. Further, since the pulse stretcher PS is provided in a stage subsequent to the beam combiner COM, it is possible to reduce the number of pulse stretchers as compared with a case of providing the pulse stretchers in both of the optical path of the first split light Bpoa1 and the optical path of the second amplified light Bpob.
(2) According to the first embodiment, the delay time T1 of the second split light Bdob2 by the first delay optical system DOb is equal to or higher than 60% and equal to or lower than 120% of the pulse width T2 of the stretched first split light Bpoa1 obtained by the pulse width of the first split light Bpoa1 being stretched by the pulse stretcher PS.

Accordingly, it is possible to reduce overlap of the pulse time waveforms Wa and Wb and increase the pulse width of the output light Bps by setting the delay time T1 to be equal to or higher than 60% of the pulse width T2, and it is possible to suppress the optical path length of the first delay optical system DOb and suppress light attenuation by setting the delay time T1 to be equal to or lower than 120%.
(3) According to the first embodiment, the optical path length of the first delay optical system DOb is equal to or longer than 90 m and equal to shorter than 180 m.

Accordingly, it is possible to increase a time difference between the first split light Bpoa1 and the second amplified light Bpob and increase the pulse width of the output light Bps by setting the optical path length to be equal to or longer than 90 m, and it is possible to suppress the light attenuation in the first delay optical system DOb by setting the optical path length to be equal to or shorter than 180 m.
(4) According to the first embodiment, the optical path length of the first delay optical system DOb is longer than the optical path length of the pulse stretcher PS.

Accordingly, the time difference due to a difference in the number of times of one cycle in the delay optical path of the pulse stretcher PS becomes shorter than the time difference between the first split light Bpoa1 and the second amplified light Bpob that enter the beam combiner COM. Therefore, light having a different number of times of one cycle in the delay optical path of the pulse stretcher PS is output from the pulse stretcher PS at a time interval shorter than the time difference between the first split light Bpoa1 and the second amplified light Bpob. Therefore, the pulse width of the output light Bps output from the pulse stretcher PS can be increased.
(5) According to the first embodiment, the energy of the second split light Bpoa2 entering the first delay optical system DOb is larger than the energy of the seed light Bmo.

Accordingly, since the energy of the second split light Bpoa2 is large, the second split light Bdob2 attenuated in the first delay optical system DOb can have the light amount sufficient as the seed light of the second amplifier POb.
(6) According to the first embodiment, the laser apparatus 100a includes the first energy sensor Epoa configured to measure the energy of the first split light Bpoa1, the second energy sensor Epob configured to measure the energy of the second amplified light Bpob, and the processor 130. The processor 130 controls the applied voltage HVpoa of the first amplifier POa based on the measurement result from the first energy sensor Epoa, and controls the applied voltage HVpob of the second amplifier POb based on the measurement result from the second energy sensor Epob.

Accordingly, by separately measuring the first split light Bpoa1 and the second amplified light Bpob and independently controlling the applied voltages HVpoa and HVpob of the first and second amplifiers POa and POb, the pulse time waveform of the combined light Bpoa1+Bpob can be accurately controlled, and sufficient energy stability can be achieved. Further, a dose amount indicating the energy of the laser beam with which one part of the semiconductor wafer is irradiated can also be stabilized.
(7) According to the first embodiment, the energy of the first amplified light Bpoa is larger than the energy of the second amplified light Bpob.

Accordingly, since the energy of the first amplified light Bpoa is large, the first split light Bpoa1 obtained by splitting the first amplified light Bpoa can have the light amount sufficient as a part of the combined light Bpoa1+Bpob.
(8) According to the first embodiment, the first split light Bpoa1 is the light transmitted through the first beam splitter BSa, the second split light Bpoa2 is the light reflected by the first beam splitter BSa, and the transmittance of the first beam splitter BSa is equal to or higher than 80% and equal to or lower than 96%.

Accordingly, the first split light Bpoa1 can have the light amount sufficient as a part of the combined light Bpoa1+Bpob, and the second split light Bdob2 obtained by delaying the second split light Bpoa2 in the first delay optical system DOb can have the light amount sufficient as the seed light of the second amplifier POb.
(9) According to the first embodiment, the first delay optical system DOb includes the relay optical system including a plurality of concave mirrors 41-46 (see FIG. 10).

Accordingly, a change in optical quality in the first delay optical system DOb can be suppressed.
(10) According to the first embodiment, the beam combiner COM brings the optical paths of the first split light Bpoa1 and the second amplified light Bpob close to each other to combine the first split light Bpoa1 and the second amplified light Bpob, and outputs the combined light Bpoa1+Bpob.

Accordingly, the combined light Bpoa1+Bpob can be generated even when wavelengths and polarization directions of the first split light Bpoa1 and the second amplified light Bpob are the same.

In other respects, the first embodiment is similar to the comparative example.

### 3. LASER APPARATUS 100b THAT FURTHER BRANCHES SECOND AMPLIFIED LIGHT BPOB

### 3.1 Configuration

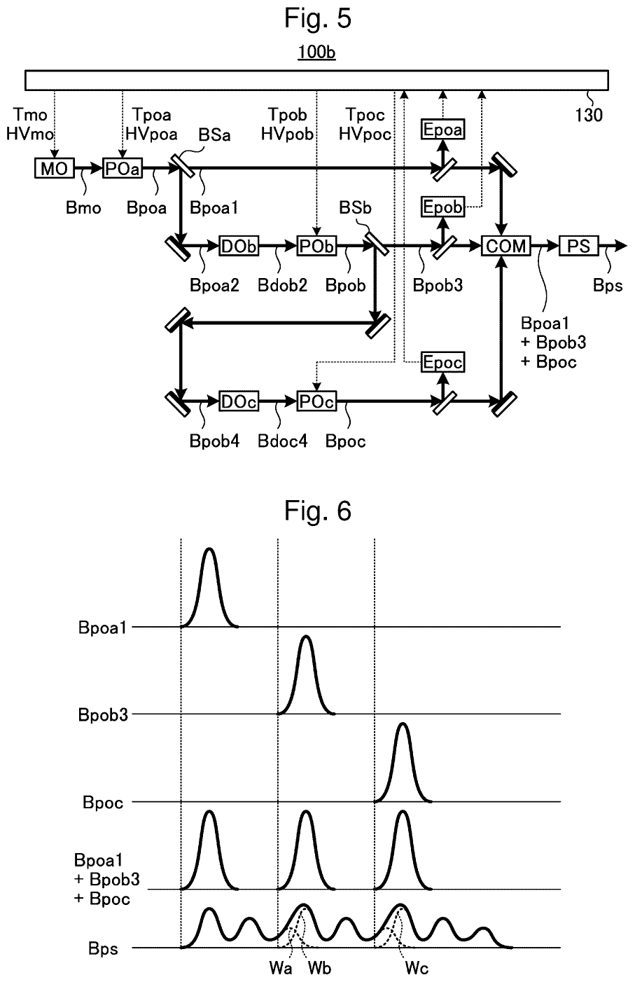

FIG. 5 schematically illustrates a configuration of a laser apparatus 100b according to a second embodiment. The laser apparatus 100b includes a second beam splitter BSb, a second delay optical system DOc, and a third amplifier POc. Configurations of the second beam splitter BSb, the second delay optical system DOc, and the third amplifier POc are the same as those of the first beam splitter BSa, the first delay optical system DOb, and the second amplifier POb in the first embodiment.

The second beam splitter BSb is disposed in the optical path of the second amplified light Bpob and splits the second amplified light Bpob into third split light Bpob3 and fourth split light Bpob4. The fourth split light Bpob4 has energy smaller than that of the third split light Bpob3. When the third split light Bpob3 is light transmitted through the second beam splitter BSb and the fourth split light Bpob4 is light reflected by the second beam splitter BSb, it is desirable that a transmittance of the second beam splitter BSb is equal to or higher than 80% and equal to or lower than 96%.

The second delay optical system DOc is disposed in an optical path of the fourth split light Bpob4, delays the fourth split light Bpob4, and outputs it as fourth split light Bdoc4. The third amplifier POc is disposed in an optical path of the delayed fourth split light Bdoc4, amplifies the fourth split light Bdoc4, and outputs third amplified light Bpoc.

The beam combiner COM is disposed in a space including three optical paths of the first split light Bpoa1, the third split light Ppob3, and the third amplified light Bpoc. The beam combiner COM brings the optical paths of the first split light Bpoa1, the third split light Ppob3 which is a part of the second amplified light Bpob, and the third amplified light Bpoc close to each other to combine the first split light Bpoa1, the third split light Ppob3, and the third amplified light Bpoc, outputs combined light Bpoa1+Bpob3+Bpoc. The configuration of the beam combiner COM will be described later with reference to FIG. 13.

The pulse stretcher PS is disposed in an optical path of the combined light Bpoa1+Bpob3+Bpoc, stretches a pulse width of the combined light Bpoa1+Bpob3+Bpoc, and outputs the output light Bps. In addition to the pulse stretcher PS disposed in the optical path of the combined light Bpoa1+Bpob3+Bpoc, or instead of the pulse stretcher PS, an unillustrated pulse stretcher may be disposed in each of the optical path of the first split light Bpoa1, the optical path of the third split light Ppob3, and the optical path of the third amplified light Bpoc.

A beam splitter having a transmittance higher than a reflectance thereof is disposed in each of the optical paths of the first split light Bpoa1, the third split light Bpob3, and the third amplified light Bpoc. The first energy sensor Epoa, the second energy sensor Epob, and a third energy sensor Epoc are disposed in respective optical paths of the light reflected by the beam splitters.

### 3.2 Operation

FIG. 6 is a time chart illustrating the pulse time waveforms of the laser beam of respective parts of the laser apparatus 100b according to the second embodiment.

### 3.2.1 Timing Control

The optical path lengths of the delay optical paths of the first and second delay optical systems DOb and DOc may be substantially the same, and a time difference between the first split light Bpoa1 and the third split light Bpob3 and a time difference between the third split light Bpob3 and the third amplified light Bpoc may be substantially the same.

The pulse time waveform of the output light Bps output from the pulse stretcher PS corresponds to a synthetic waveform of pulse time waveforms Wa, Wb, and Wc when the pulse widths of the first split light Bpoa1, the third split light Bpob3, and the third amplified light Bpoc are stretched by the pulse stretcher PS.

Delay time of the fourth split light Bdoc4 delayed by the second delay optical system DOc is desirably equal to or higher than 60% and equal to or lower than 120% of a pulse width of the pulse time waveform Wb.

### 3.2.2 Energy Control

A pulse time waveform of the combined light Bpoa1+Bpob3+Bpoc corresponds to a synthetic waveform of the first split light Bpoa1, the third split light Bpob3, and the third amplified light Bpoc, and is controlled as follows. The energy of the first split light Bpoa1, the energy of the third split light Bpob3, and energy of the third amplified light Bpoc are measured by the first, second, and third energy sensors Epoa, Epob, and Epoc, respectively. The processor 130 controls the applied voltage HVpoa of the first amplifier POa based on the measurement result from the first energy sensor Epoa, controls the applied voltage HVpob of the second amplifier POb based on the measurement result from the second energy sensor Epob, and controls an applied voltage HVpoc of the third amplifier POc based on a measurement result from the third energy sensor Epoc.

Alternatively, the pulse time waveform of the combined light Bpoa1+Bpob3+Bpoc may be measured by an unillustrated energy sensor, and the processor 130 may calculate the energy of the first portion corresponding to the first split light Bpoa1 of the pulse time waveform of the combined light Bpoa1+Bpob3+Bpoc, the energy of the second portion corresponding to the third split light Bpob3, and energy of a third portion corresponding to the third amplified light Bpoc. Further, the pulse time waveform of the output light Bps may be measured by an unillustrated energy sensor, and the processor 130 may calculate the energy of the first portion corresponding to a part of the pulse time waveform Wa of the pulse time waveform of the output light Bps, the energy of the second portion corresponding to a part of the pulse time waveform Wb, and the energy of the third portion corresponding to a part of the pulse time waveform Wc. In any cases, the processor 130 may control the applied voltage HVpoa of the first amplifier POa based on the energy of the first portion, control the applied voltage HVpob of the second amplifier POb based on the energy of the second portion, and control the applied voltage HVpoc of the third amplifier POc based on the energy of the third portion.

The first split light Bpoa1, the third split light Bpob3, and the third amplified light Bpoc may have the same energy. Since the first split light Bpoa1 is generated by being branched from the first amplified light Bpoa and the third split light Bpob3 is generated by being branched from the second amplified light Bpob, the energy of each of the first amplified light Bpoa and the second amplified light Bpob may be larger than the energy of each of the first split light Bpoa1, the third split light Bpob3, and the third amplified light Bpoc. Further, the difference in the energy between the third split light Bpob3 and the third amplified light Bpoc may be smaller than the difference in the energy between the third and fourth split light Bpob3 and Bpob4.

### 3.3 Effect

(11) According to the second embodiment, the laser apparatus 100b includes the following components in addition to the components of the laser apparatus 100a.
(h) The second beam splitter BSb configured to split the second amplified light Bpob into the third split light Bpob3 and the fourth split light Bpob4 having the energy smaller than that of the third split light Bpob3,
(i) the second delay optical system DOc configured to delay the fourth split light Bpob4, and
(j) the third amplifier POc configured to amplify the delayed fourth split light Bdoc4 and to output the third amplified light Bpoc.

In the second embodiment, the beam combiner COM combines the first split light Bpoa1, the third split light Bpob3 which is a part of the second amplified light Bpob, and the third amplified light Bpoc, and outputs the combined light Bpoa1+Bpob3+Bpoc.

Accordingly, by combining the first split light Bpoa1, the third split light Bpob3, and the third amplified light Bpoc of which timings are shifted from each other and stretching the pulse width of the combined light Bpoa1+Bpob3+Bpoc, the pulse width can be further increased. Since the second amplified light Bpob is split in a stage subsequent to the second amplifier POb, beam characteristics other than output timings of the third and fourth split light Bpob3 and Bpob4 can be the same as those of the first and second split light Bpoa1 and Bpoa2. Therefore, the first and second delay optical systems DOb and DOc can have same specifications, and the second and third amplifiers POb and POc can have the same specifications.
(12) According to the second embodiment, the laser apparatus 100b includes the first energy sensor Epoa configured to measure the energy of the first split light Bpoa1, the second energy sensor Epob configured to measure the energy of the third split light Bpob3, the third energy sensor Epoc configured to measure the energy of the third amplified light Bpoc, and the processor 130. The processor 130 controls the applied voltage HVpoa of the first amplifier POa based on the measurement result from the first energy sensor Epoa, controls the applied voltage HVpob of the second amplifier POb based on the measurement result from the second energy sensor Epob, and controls the applied voltage HVpoc of the third amplifier POc based on the measurement result from the third energy sensor Epoc.

Accordingly, by separately measuring the first split light Bpoa1, the third split light Bpob3, and the third amplified light Bpoc and independently controlling the applied voltages HVpoa, HVpob, and HVpoc of the first, second, and third amplifiers POa, POb, and POc, the pulse time waveform of the combined light Bpoa1+Bpob3+Bpoc can be accurately controlled.
(13) According to the second embodiment, the energy of each of the first amplified light Bpoa and the second amplified light Bpob is larger than the energy of the third amplified light Bpoc.

Accordingly, since the energy of each of the first amplified light Bpoa and the second amplified light Bpob is large, each of the first split light Bpoa1 and the third split light Bpob3 obtained by splitting the first amplified light Bpoa and the second amplified light Bpob respectively can have the light amount sufficient as a part of the combined light Bpoa1+Bpob3+Bpoc.
(14) According to the second embodiment, the third split light Bpob3 is the light transmitted through the second beam splitter BSb, the fourth split light Bpob4 is the light reflected by the second beam splitter BSb, and the transmittance of the second beam splitter BSb is equal to or higher than 80% and equal to or lower than 96%.

Accordingly, the third split light Bpob3 can have the light amount sufficient as a part of the combined light Bpoa1+Bpob3+Bpoc, and the fourth split light Bdoc4 can have the light amount sufficient as the seed light of the third amplifier POc.

In other respects, the second embodiment is similar to the first embodiment.

### 4. LASER APPARATUS 100c THAT FURTHER BRANCHES SECOND SPLIT LIGHT BPOA2

### 4.1 Configuration

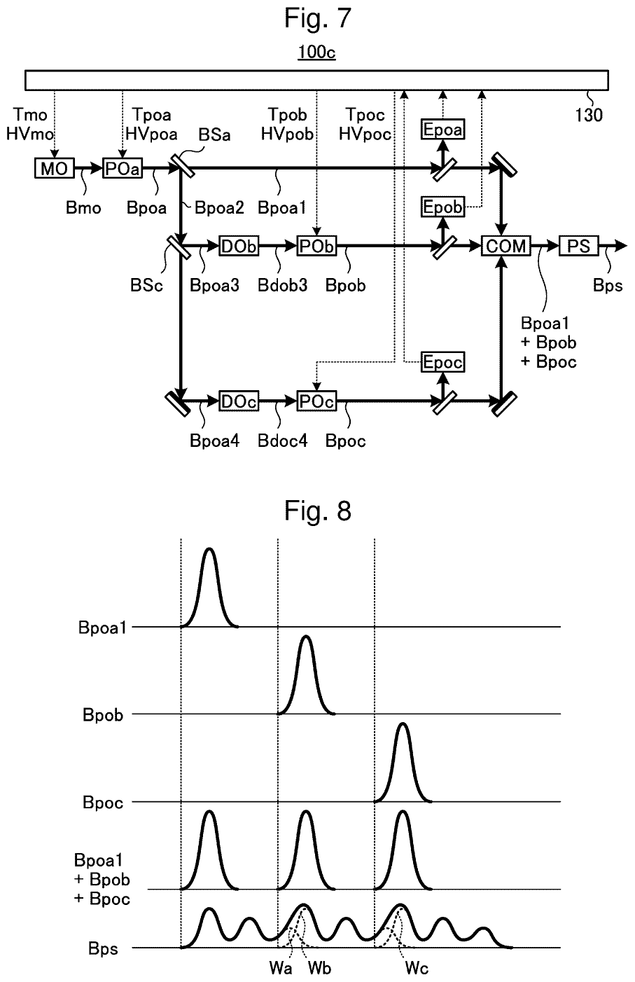

FIG. 7 schematically illustrates a configuration of a laser apparatus 100c according to a third embodiment. The laser apparatus 100c includes a second beam splitter BSc, the second delay optical system DOc, and the third amplifier POc. Configurations of the second delay optical system DOc and the third amplifier POc are the same as those of the first delay optical system DOb and the second amplifier POb in the first embodiment.

The second beam splitter BSc is disposed in the optical path of the second split light Bpoa2 and splits the second split light Bpoa2 into third split light Bpoa3 and fourth split light Bpoa4. The third split light Bpoa3 is light reflected by the second beam splitter BSc, and the fourth split light Bpoa4 is light transmitted through the second beam splitter BSc. The first delay optical system DOb delays the third split light Bpoa3 which is a part of the second split light Bpoa2, and the second amplifier POb amplifies delayed third split light Bdob3 and outputs the second amplified light Bpob.

The second delay optical system DOc is disposed in an optical path of the fourth split light Bpoa4, delays the fourth split light Bpoa4, and outputs it as the fourth split light Bdoc4. The third amplifier POc is disposed in the optical path of the delayed fourth split light Bdoc4, amplifies the fourth split light Bdoc4, and outputs the third amplified light Bpoc.

An optical path length of a delay optical path of the second delay optical system DOc is longer than that of the first delay optical system DOb. The optical path length of the delay optical path of the second delay optical system DOc may be approximately twice that of the first delay optical system DOb, and the light is significantly attenuated more in the second delay optical system DOc than in the first delay optical system DOb. In order to make the energy of the seed light of the third amplifier POc same as that of the seed light of the second amplifier POb, the energy of the fourth split light Bpoa4 is made larger than the energy of the third split light Bpoa3. Therefore, a reflectance of the second beam splitter BSc is desirably equal to or higher than 20% and equal to or lower than 40%.

While the seed light of the second amplifier POb is obtained from the second split light Bpoa2 reflected by the first beam splitter BSa in the first and second embodiments, the seed light of both the second and third amplifiers POb and POc needs to be obtained from the second split light Bpoa2 reflected by the first beam splitter BSa in the third embodiment. Therefore, the transmittance of the first beam splitter BSa is desirably equal to or higher than 70% and equal to or lower than 90%.

The beam combiner COM is disposed in a space including three optical paths of the first split light Bpoa1, second amplified light Ppob, and the third amplified light Bpoc. The beam combiner COM brings the optical paths of the first split light Bpoa1, the second amplified light Bpob, and the third amplified light Bpoc close to each other to combine the first split light Bpoa1, the second amplified light Bpob, and the third amplified light Bpoc, and outputs combined light Bpoa1+Bpob+Bpoc.

The pulse stretcher PS is disposed in an optical path of the combined light Bpoa1+Bpob+Bpoc, stretches a pulse width of the combined light Bpoa1+Bpob+Bpoc, and outputs the output light Bps. In addition to the pulse stretcher PS disposed in the optical path of the combined light Bpoa1+Bpob+Bpoc, or instead of the pulse stretcher PS, an unillustrated pulse stretcher may be disposed in each of the optical path of the first split light Bpoa1, the optical path of the second amplified light Ppob, and the optical path of the third amplified light Bpoc.

A beam splitter having a transmittance higher than a reflectance thereof is disposed in each of the optical paths of the first split light Bpoa1, the second amplified light Bpob, and the third amplified light Bpoc. The first energy sensor Epoa, the second energy sensor Epob, and the third energy sensor Epoc are disposed in respective optical paths of the light reflected by the beam splitters.

### 4.2 Operation

FIG. 8 is a time chart illustrating pulse time waveforms of the laser beam of respective parts of the laser apparatus 100c according to the third embodiment.

### 4.2.1 Timing Control

A time difference between the first split light Bpoa1 and the second amplified light Bpob and a time difference between the second amplified light Bpob and the third amplified light Bpoc may be substantially the same.

The pulse time waveform of the output light Bps output from the pulse stretcher PS corresponds to the synthetic waveform of the pulse time waveform Wa, Wb and Wc when pulse widths of the first split light Bpoa1, the second amplified light Bpob, and the third amplified light Bpoc are stretched by the pulse stretcher PS.

The delay time of the fourth split light Bdoc4 delayed by the second delay optical system DOc is desirably equal to or higher than 120% and equal to or lower than 240% of a pulse width of the pulse time waveform Wa. A desirable range of the optical path length of the delay optical path of the second delay optical system DOc is preferably equal to or longer than 180 m and equal to or shorter than 360 m. Further, the optical path length of the second delay optical system DOc is longer than twice the optical path length of the pulse stretcher PS, and is preferably 4 times or more the optical path length of the pulse stretcher PS.

### 4.2.2 Energy Control

A pulse time waveform of the combined light Bpoa1+Bpob+Bpoc corresponds to a synthetic waveform of the first split light Bpoa1, the second amplified light Bpob, and the third amplified light Bpoc, and is controlled as follows. The energy of the first split light Bpoa1, the energy of the second amplified light Bpob, and the energy of the third amplified light Bpoc are measured by the first, second, and third energy sensors Epoa, Epob, and Epoc, respectively. The processor 130 controls the applied voltage HVpoa of the first amplifier POa based on the measurement result from the first energy sensor Epoa, controls the applied voltage HVpob of the second amplifier POb based on the measurement result from the second energy sensor Epob, and controls the applied voltage HVpoc of the third amplifier POc based on the measurement result from the third energy sensor Epoc.

Alternatively, the pulse time waveform of the combined light Bpoa1+Bpob+Bpoc may be measured by an unillustrated energy sensor, and the processor 130 may calculate the energy of the first portion corresponding to the first split light Bpoa1 of the pulse time waveform of the combined light Bpoa1+Bpob+Bpoc, the energy of the second portion corresponding to the second amplified light Bpob, and the energy of the third portion corresponding to the third amplified light Bpoc, for example. Further, the pulse time waveform of the output light Bps may be measured by an unillustrated energy sensor, and the processor 130 may calculate the energy of the first portion corresponding to a part of the pulse time waveform Wa of the pulse time waveform of the output light Bps, the energy of the second portion corresponding to a part of the pulse time waveform Wb, and the energy of the third portion corresponding to a part of the pulse time waveform Wc. In any cases, the processor 130 may control the applied voltage HVpoa of the first amplifier POa based on the energy of the first portion, control the applied voltage HVpob of the second amplifier POb based on the energy of the second portion, and control the applied voltage HVpoc of the third amplifier POc based on the energy of the third portion.

The first split light Bpoa1, the second amplified light Bpob, and the third amplified light Bpoc may have the same energy. Since the first split light Bpoa1 is generated by being branched from the first amplified light Bpoa, the energy of the first amplified light Bpoa may be larger than the energy of each of the second amplified light Bpob and the third amplified light Bpoc.

### 4.3 Effect

(15) According to the third embodiment, the laser apparatus 100c includes the following components in addition to the components of the laser apparatus 100a.
(h) The second beam splitter BSc configured to split the second split light Bpoa2 into the third split light Bpoa3 and the fourth split light Bpoa4,
(i) the second delay optical system DOc configured to delay the fourth split light Bpoa4, and
(j) the third amplifier POc configured to amplify the delayed fourth split light Bdoc4 and to output the third amplified light Bpoc.

In the third embodiment, the first delay optical system DOb delays the third split light Bpoa3 which is a part of the second split light Bpoa2. The second amplifier POb amplifies the delayed third split light Bdob3 and outputs the second amplified light Bpob. The beam combiner COM combines the first split light Bpoa1, the second amplified light Bpob, and the third amplified light Bpoc, and outputs the combined light Bpoa1+Bpob+Bpoc.

Accordingly, by combing the first split light Bpoa1, the second amplified light Bpob, and the third amplified light Bpoc of which timings are shifted from each other and stretching the pulse width of the combined light Bpoa1+Bpob+Bpoc, the pulse width can be further increased. Since the second split light Bpoa2 is split in a stage subsequent to the first amplifier POa, even when just one oscillator MO is used and further even when the light amount is attenuated in the first and second delay optical systems DOb and DOc, it is possible to obtain the third and fourth split light Bdob3 and Bdoc4 having the light amount sufficient as the seed light of the second and third amplifiers POb and POc while suppressing the load of the oscillator MO.
(16) According to the third embodiment, the optical path length of the second delay optical system DOc is longer than the optical path length of the first delay optical system DOb.

Accordingly, since the optical path lengths of the first and second delay optical systems DOb and DOc are different, the timings of the second and third amplified light Bpob and Bpoc can be shifted from each other.
(17) According to the third embodiment, the third split light Bpoa3 is the light reflected by the second beam splitter BSc, the fourth split light Bpoa4 is the light transmitted through the second beam splitter BSc, and the reflectance of the second beam splitter BSc is equal to or higher than 20% and equal to or lower than 40%.

Accordingly, by making the energy of the fourth split light Bpoa4 larger than that of the third split light Bpoa3, even when the attenuation in the second delay optical system DOc is larger than the attenuation in the first delay optical system DOb, the fourth split light Bdoc4 can have the light amount sufficient as the seed light of the third amplifier POc.
(18) According to the third embodiment, the first split light Bpoa1 is the light transmitted through the first beam splitter BSa, the second split light Bpoa2 is the light reflected by the first beam splitter BSa, and the transmittance of the first beam splitter BSa is equal to or higher than 70% and equal to or lower than 90%.

Accordingly, the third and fourth split light Bdob3 and Bdoc4 can have the light amount sufficient as the seed light of the second and third amplifiers POb and POc.
(19) According to the third embodiment, the laser apparatus 100c includes the first energy sensor Epoa configured to measure the energy of the first split light Bpoa1, the second energy sensor Epob configured to measure the energy of the second amplified light Bpob, the third energy sensor Epoc configured to measure the energy of the third amplified light Bpoc, and the processor 130. The processor 130 controls the applied voltage HVpoa of the first amplifier POa based on the measurement result from the first energy sensor Epoa, controls the applied voltage HVpob of the second amplifier POb based on the measurement result from the second energy sensor Epob, and controls the applied voltage HVpoc of the third amplifier POc based on the measurement result from the third energy sensor Epoc.

Accordingly, by separately measuring the first split light Bpoa1, the second amplified light Bpob, and the third amplified light Bpoc and independently controlling the applied voltages HVpoa, HVpob, and HVpoc of the first, second, and third amplifiers POa, POb, and POc, the pulse time waveform of the combined light Bpoa1+Bpob+Bpoc can be accurately controlled.

In other respects, the third embodiment is similar to the first embodiment.

### 5. OTHERS

### 5.1 Control of Applied Voltage

FIG. 9 is a flowchart of the control of the applied voltage executed by the processor 130 in the first to third embodiments. In FIG. 9, the following seven kinds of controls will be collectively described as the control of an applied voltage HV based on energy E of the laser beam.
(a) Control of the applied voltage HVmo of the oscillator MO based on the energy of the seed light Bmo measured by an unillustrated energy sensor
(b) Control of the applied voltage HVpoa of the first amplifier POa based on the energy of the first split light Bpoa1 measured by the first energy sensor Epoa
(c) Control of the applied voltage HVpob of the second amplifier POb based on the energy of the second amplified light Bpob or the third split light Bpob3 measured by the second energy sensor Epob
(d) Control of the applied voltage HVpoc of the third amplifier POc based on the energy of the third amplified light Bpoc measured by the third energy sensor Epoc
(e) Control of the applied voltage HVpoa of the first amplifier POa based on the energy of the first portion of the output light Bps, the combined light Bpoa1+Bpob, the combined light Bpoa1+Bpob3+Bpoc, or the combined light Bpoa1+Bpob+Bpoc, measured by an unillustrated energy sensor
(f) Control of the applied voltage HVpob of the second amplifier POb based on the energy of the second portion of the output light Bps, the combined light Bpoa1+Bpob, the combined light Bpoa1+Bpob3+Bpoc, or the combined light Bpoa1+Bpob+Bpoc, measured by an unillustrated energy sensor
(g) Control of the applied voltage HVpoc of the third amplifier POc based on the energy of the third portion of the output light Bps, the combined light Bpoa1+Bpob3+Bpoc, or the combined light Bpoa1+Bpob+Bpoc, measured by an unillustrated energy sensor

In S1, the processor 130 acquires a result of measuring the energy E of the laser beam while changing the applied voltage HV, and calculates a slope k of the energy E with respect to the applied voltage HV. This calculation is performed at regular intervals.

In S2, the processor 130 outputs an oscillation trigger signal to cause the laser beam of one pulse to be output.

In S3, the processor 130 acquires a measurement result of the energy E of the laser beam, and calculates a difference ΔE from a target value.

In S4, the processor 130 calculates a correction amount ΔHV of the applied voltage HV by an equation below.

ΔHV=ΔE/k

In S5, the processor 130 corrects the applied voltage HV of the subsequent pulse using the correction amount ΔHV.

After S5, the processor 130 returns processing to S2. As described above, the applied voltage HV is controlled so that the energy E of the laser beam approaches the target value.

### 5.2 Configuration of Delay Optical System

FIG. 10 illustrates a configuration example of the first delay optical system DOb used in the first and second embodiments. The first delay optical system DOb includes the concave mirrors 41-46. The concave mirrors 41-46 are disposed so as to reflect the second split light Bpoa2 in an ascending order of the numbers. The relay optical system is configured by such disposition that a distance L between the mirrors adjacent to each other on the optical path is equal to a curvature radius R of each of the concave mirrors 41-46. A value obtained by multiplying the number of the concave mirrors by the distance L is the optical path length of the first delay optical system DOb.

The first delay optical system DOb illustrated in FIG. 10 can also be used in the third embodiment. In that case, the third split light Bpoa3 enters the concave mirrors 41-46 instead of the second split light Bpoa2. The second delay optical system DOc used in the second and third embodiments may be similar to the first delay optical system DOb.

### 5.3 Configuration of Beam Combiner COM

FIG. 11 illustrates a first configuration example of the beam combiner COM used in the first embodiment. The beam combiner COM according to the first configuration example includes a prism mirror 51 coated with a high reflective film 511.

The first split light Bpoa1 and the second amplified light Bpob enter the beam combiner COM through the optical paths perpendicular to each other. A high reflective surface coated with the high reflective film 511 is inclined by 45 degrees with respect to both the first split light Bpoa1 and the second amplified light Bpob. The high reflective surface and another surface of the prism mirror 51 form a ridge line 510 at an angle of 45 degrees or lower. The second amplified light Bpob does not enter the prism mirror 51, and passes through a position as close as possible to the ridge line 510 of the prism mirror 51. The first split light Bpoa1 is incident on the high reflective surface at a position as close as possible to the ridge line 510, and is reflected in a direction parallel to the second amplified light Bpob. Thus, the first split light Bpoa1 and the second amplified light Bpob can be brought close to each other.

FIG. 12 illustrates a second configuration example of the beam combiner COM used in the first embodiment. The beam combiner COM according to the second configuration example has a configuration in which a part of a planar substrate 52 transparent to the second amplified light Bpob is coated with a high reflective film 521 and the other part is coated with a reflection suppressing film.

The first split light Bpoa1 and the second amplified light Bpob enter the planar substrate 52 through optical paths perpendicular to each other. A high reflective surface coated with the high reflective film 521 is inclined by 45 degrees with respect to both the first split light Bpoa1 and the second amplified light Bpob. The second amplified light Bpob is transmitted through a part coated with the reflection suppressing film at a position as close as possible to a boundary with the part coated with the high reflective film 521. The first split light Bpoa1 enters a part coated with the high reflective film 521 at a position as close as possible to a boundary with the part coated with the reflection suppressing film, and is reflected in a direction parallel to the second amplified light Bpob. Thus, the first split light Bpoa1 and the second amplified light Bpob can be brought close to each other.

FIG. 13 illustrates a third configuration example of the beam combiner COM used in the second embodiment. The beam combiner COM according to the third configuration example includes a prism mirror 53 coated with a high reflective film 531 and a prism mirror 54 coated with a high reflective film 541.

The first split light Bpoa1 and the third amplified light Bpoc enter the beam combiner COM through optical paths in directions opposite to each other, and the third split light Bpob3 enters the beam combiner COM through an optical path perpendicular to both the first split light Bpoa1 and the third amplified light Bpoc. A high reflective surface coated with the high reflective film 531 and a high reflective surface coated with the high reflective film 541 are inclined by 45 degrees with respect to each of the first split light Bpoa1, the third split light Bpob3, and the third amplified light Bpoc.

The high reflective surface and another surface of the prism mirror 53 form a ridge line 530 at an angle of 45 degrees or lower, and the high reflective surface and another surface of the prism mirror 54 form a ridge line 540 at an angle of 45 degrees or lower. A distance between the ridge line 530 and the ridge line 540 is approximately equal to a beam width of the third split light Bpob3.

The third split light Bpob3 does not enter either of the prism mirrors 53 and 54 and passes between the ridge lines 530 and 540 of the prism mirrors 53 and 54. The first split light Bpoa1 is incident on the high reflective surface of the prism mirror 53 at a position as close as possible to the ridge line 530, and is reflected in a direction parallel to the third split light Bpob3. The third amplified light Bpoc is incident on the high reflective surface of the prism mirror 54 at a position as close as possible to the ridge line 540, and is reflected in a direction parallel to the third split light Bpob3. Accordingly, the first split light Bpoa1, the third split light Bpob3, and the third amplified light Bpoc can be brought close to each other.

The beam combiner COM illustrated in FIG. 13 can also be used in the third embodiment. In that case, instead of the third split light Bpob3, the second amplified light Bpob passes between the ridge lines 530 and 540.

In the second and third embodiments, the three beams may be brought close to each other by combining the two beam combiners COM illustrated in FIG. 11 or FIG. 12.

### 5.4 Supplements

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser apparatus comprising:
an oscillator configured to output seed light in a pulse form;
a first amplifier configured to amplify the seed light and to output first amplified light;
a first beam splitter configured to split the first amplified light into first split light and second split light having energy smaller than energy of the first split light;
a first delay optical system configured to delay the second split light;
a second amplifier configured to amplify the delayed second split light and to output second amplified light;
a beam combiner configured to combine the first split light and the second amplified light and to output combined light; and
a pulse stretcher configured to stretch a pulse width of the combined light.

2. The laser apparatus according to claim 1, wherein
delay time of the second split light by the first delay optical system is equal to or higher than 60% and equal to or lower than 120% of a pulse width of a stretched first split light obtained by a pulse width of the first split light being stretched by the pulse stretcher.

3. The laser apparatus according to claim 1, wherein
an optical path length of the first delay optical system is equal to or longer than 90 m and equal to or shorter than 180 m.

4. The laser apparatus according to claim 1, wherein
an optical path length of the first delay optical system is longer than an optical path length of the pulse stretcher.

5. The laser apparatus according to claim 1, wherein
energy of the second split light entering the first delay optical system is larger than energy of the seed light.

6. The laser apparatus according to claim 1, further comprising:
a first energy sensor configured to measure energy of the first split light;
a second energy sensor configured to measure energy of the second amplified light; and
a processor, wherein
the processor controls an applied voltage of the first amplifier based on a measurement result from the first energy sensor, and controls an applied voltage of the second amplifier based on a measurement result from the second energy sensor.

7. The laser apparatus according to claim 1, wherein
energy of the first amplified light is larger than energy of the second amplified light.

8. The laser apparatus according to claim 1, wherein
the first split light is light transmitted through the first beam splitter,
the second split light is light reflected by the first beam splitter, and
a transmittance of the first beam splitter is equal to or higher than 80% and equal to or lower than 96%.

9. The laser apparatus according to claim 1, wherein
the first delay optical system includes a relay optical system including a plurality of concave mirrors.

10. The laser apparatus according to claim 1, wherein
the beam combiner brings optical paths of the first split light and the second amplified light close to each other to combine the first split light and the second amplified light, and outputs the combined light.

11. The laser apparatus according to claim 1, further comprising:
a second beam splitter configured to split the second amplified light into third split light and fourth split light having energy smaller than energy of the third split light;
a second delay optical system configured to delay the fourth split light; and
a third amplifier configured to amplify the delayed fourth split light and to output third amplified light, wherein
the beam combiner combines the first split light beam, the third split light which is a part of the second amplified light, and the third amplified light, and outputs the combined light.

12. The laser apparatus according to claim 11, further comprising:
a first energy sensor configured to measure energy of the first split light;
a second energy sensor configured to measure energy of the third split light;
a third energy sensor configured to measure energy of the third amplified light; and
a processor, wherein
the processor controls an applied voltage of the first amplifier based on a measurement result from the first energy sensor, controls an applied voltage of the second amplifier based on a measurement result from the second energy sensor, and controls an applied voltage of the third amplifier based on a measurement result from the third energy sensor.

13. The laser apparatus according to claim 11, wherein
energy of each of the first amplified light and the second amplified light is larger than energy of the third amplified light.

14. The laser apparatus according to claim 11, wherein
the third split light is light transmitted through the second beam splitter,
the fourth split light is light reflected by the second beam splitter, and
a transmittance of the second beam splitter is equal to or higher than 80% and equal to or lower than 96%.

15. The laser apparatus according to claim 1, further comprising:
a second beam splitter configured to split the second split light into third split light and fourth split light;
a second delay optical system configured to delay the fourth split light; and
a third amplifier configured to amplify the delayed fourth split light and to output third amplified light, wherein
the first delay optical system delays the third split light which is a part of the second split light,
the second amplifier amplifies the delayed third split light and outputs the second amplified light, and
the beam combiner combines the first split light, the second amplified light, and the third amplified light, and outputs the combined light.

16. The laser apparatus according to claim 15, wherein
an optical path length of the second delay optical system is longer than an optical path length of the first delay optical system.

17. The laser apparatus according to claim 15, wherein
the third split light is light reflected by the second beam splitter,
the fourth split light is light transmitted through the second beam splitter, and
a reflectance of the second beam splitter is equal to or higher than 20% and equal to or lower than 40%.

18. The laser apparatus according to claim 15, wherein
the first split light is light transmitted through the first beam splitter,
the second split light is light reflected by the first beam splitter, and
a transmittance of the first beam splitter is equal to or higher than 70% and equal to or lower than 90%.

19. The laser apparatus according to claim 15, further comprising:
a first energy sensor configured to measure energy of the first split light;
a second energy sensor configured to measure energy of the second amplified light;
a third energy sensor configured to measure energy of the third amplified light; and
a processor, wherein
the processor controls an applied voltage of the first amplifier based on a measurement result from the first energy sensor, controls an applied voltage of the second amplifier based on a measurement result from the second energy sensor, and controls an applied voltage of the third amplifier based on a measurement result from the third energy sensor.

20. An electronic device manufacturing method comprising:
generating a laser beam with a laser apparatus, the laser apparatus including
an oscillator configured to output seed light in a pulse form,
a first amplifier configured to amplify the seed light and to output first amplified light,
a first beam splitter configured to split the first amplified light into first split light and second split light having energy smaller than energy of the first split light,
a first delay optical system configured to delay the second split light,
a second amplifier configured to amplify the delayed second split light and to output second amplified light,
a beam combiner configured to combine the first split light and the second amplified light and to output combined light, and
a pulse stretcher configured to stretch a pulse width of the combined light;
outputting the laser beam to an exposure apparatus; and
exposing a photosensitive substrate to the laser beam within the exposure apparatus to manufacture an electronic device.
